(19) United States
(12) Patent Application Publication
(10) Pub. No.: US 2022/0310874 A1
(43) Pub. Date: Sep. 29, 2022

(54) GROUP III NITRIDE SEMICONDUCTOR DEVICE AND METHOD FOR PRODUCING SAME

(71) Applicant: TOYODA GOSEI CO., LTD., Kiyosu-shi (JP)

(72) Inventor: Koji OKUNO, Kiyosu-shi (JP)

(21) Appl. No.: 17/703,656

(22) Filed: Mar. 24, 2022

(30) Foreign Application Priority Data
Mar. 29, 2021 (JP) 2021-056316

(51) Int. Cl. H01L 33/12; H01L 33/00; H01L 33/06; H01L 33/32; H01S 5/343

(52) U.S. Cl. CPC H01L 33/12; H01L 33/007; H01L 33/06; H01L 33/32; H01S 5/34333; H01S 5/34346

(57) ABSTRACT

An n-side composition gradient layer includes an intermediate layer and composition continuous gradient layers. The intermediate layer is the group III nitride semiconductor layer containing In. The composition continuous gradient layers are group III nitride semiconductor layers in which an In composition changes in a direction perpendicular to a boundary surface between a well layer and a barrier layer. A thickness of the intermediate layer is thinner than a thickness of the well layer. An In composition of the intermediate layer is equal to or less than an In composition of the well layer. In the composition continuous gradient layers, the In composition continuously changes in a streamline manner toward the intermediate layer.

### CROSS-REFERENCE TO RELATED APPLICATIONS

The present application claims the benefit of priority of Japanese Patent Application No. 2021-056316, filed on Mar. 29, 2021, the content of which is incorporated herein by reference.

### TECHNICAL FIELD

The technical field of the present specification relates to a group III nitride semiconductor device and a method for producing the semiconductor device.

### BACKGROUND ART

Group III nitride semiconductors are applied to light emitting devices, laser diodes, light receiving devices, and the like. In the light emitting device and the laser diode, when strain occurs between a substrate and an active layer, brightness decreases. The strain deteriorates crystallinity of a semiconductor, and a non-light emitting center may be formed. In addition, the strain may distort a band structure, and overlaps between electrons and holes may be reduced, resulting in a decrease in luminous probability. These phenomena are remarkable in an InGaN well layer having a large In composition, that is, an InGaN well layer having an emission wavelength of blue-green to red, for example, 450 nm or more. This is because a difference in lattice constant between the well layer and a foundation layer is very large, and thus crystal quality of the well layer is likely to be deteriorated and characteristics of the well layer are likely to be deteriorated due to a piezoelectric field. Therefore, a technique for mitigating the strain has been developed.

For example, Patent Literature 1 discloses a technique of forming a superlattice layer between a substrate and a light emitting layer. The superlattice layer is formed by alternately and repeatedly forming two types of semiconductor layers having different compositions. Thereby, strain applied to the light emitting layer is mitigated (see paragraph of JP-A-2000-31591).

### SUMMARY OF INVENTION

However, it is necessary to repeatedly form many layers of the superlattice. Therefore, a growth time of the semiconductor light emitting device is long. In addition, a stacked structure of the semiconductor is also complicated.

An object of the present specification is to provide a group III nitride semiconductor device having a simple structure and capable of mitigating strain applied to an active layer, and a method for producing the same.

A group III nitride semiconductor device according to a first aspect includes a substrate, an active layer, and a foundation layer between the substrate and the active layer. The active layer includes a well layer and a barrier layer. The foundation layer includes a composition continuous gradient layer. The well layer is a group III nitride semiconductor layer containing In. The barrier layer is a group III nitride semiconductor layer. The composition continuous gradient layer is a group III nitride semiconductor layer in which an In composition changes in a direction perpendicular to a boundary surface between the well layer and the barrier layer. In the composition continuous gradient layer, the In composition continuously changes in a streamline manner.

In this group III nitride semiconductor device, the composition continuous gradient layers mitigate strain applied to the light emitting layer. The composition continuous gradient layer does not have a repeating structure. It is not necessary to form a superlattice structure in this group III nitride semiconductor device. A thickness of an n-type semiconductor layer between an n-type contact layer and the active layer may be small. Therefore, an electrical resistance of the semiconductor device is lower than an electrical resistance of the semiconductor device in the related art. In addition, crystal quality of the semiconductor above the composition continuous gradient layer is improved. In addition, a piezoelectric field is weakened. As a result, a threshold voltage or a threshold current of the semiconductor light emitting device can be reduced.

The present specification provides a group III nitride semiconductor device having a simple structure and capable of mitigating strain applied to an active layer, and a method for producing the same.

### BRIEF DESCRIPTION OF DRAWINGS

FIG. 1 is a schematic configuration diagram of a light emitting device 100 according to a first embodiment.

FIG. 2 is a diagram showing a relationship between a band structure and a stacked structure of an n-side composition gradient layer 150 and a light emitting layer 160 of the light emitting device 100 according to the first embodiment.

FIG. 3 is a diagram (part 1) showing a method for forming the n-side composition gradient layer 150 and the light emitting layer 160 of the light emitting device 100 according to the first embodiment.

FIG. 4 is a diagram (part 2) showing the method for forming the n-side composition gradient layer 150 and the light emitting layer 160 of the light emitting device 100 according to the first embodiment.

FIG. 5 is a schematic configuration diagram of a laser device 200 according to a second embodiment.

FIG. 6 is a graph (part 1) showing a relationship between a flow rate of hydrogen gas in a carrier gas and an In composition of a semiconductor.

FIG. 7 is a graph (part 2) showing the relationship between the flow rate of hydrogen gas in the carrier gas and the In composition of the semiconductor.

FIG. 8 is an AFM image of a surface of the light emitting layer when the n-side composition gradient layer is formed.

FIG. 9 is an AFM image of the surface of the light emitting layer without the n-side composition gradient layer.

FIG. 10 is a graph showing a photoluminescence intensity of a semiconductor light emitting device when the n-side composition gradient layer is formed.

### DESCRIPTION OF EMBODIMENTS

Hereinafter, specific embodiments will be described with reference to the drawings by taking a group III nitride semiconductor device and a method for producing the semiconductor device as examples. However, the technique of the present specification is not limited to the embodiments. A stacked structure of layers of the semiconductor device and an electrode structure described later are exemplified. Of course, a stacked structure different from those of the embodiments may be used. A ratio of thicknesses of layers in each figure is conceptually shown, and a ratio of actual thicknesses is not indicated.

### First Embodiment

### 1. Semiconductor Light Emitting Device (LED)

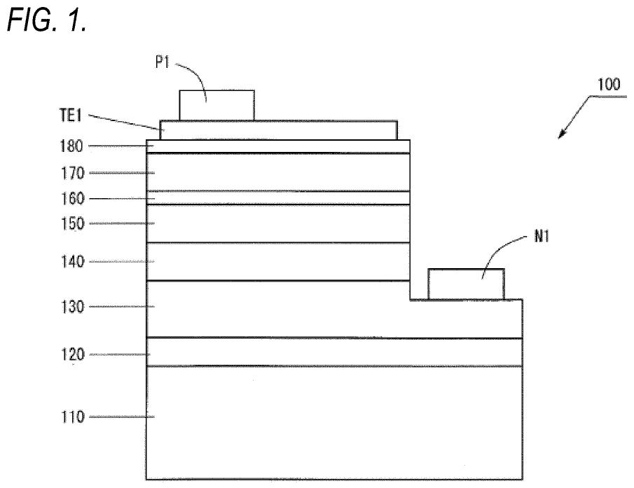

FIG. 1 is a schematic configuration diagram of a light emitting device 100 according to a first embodiment. The light emitting device 100 is a face-up semiconductor light emitting device. The light emitting device 100 includes a plurality of semiconductor layers made of a group III nitride semiconductor. As shown in FIG. 1, the light emitting device 100 includes a substrate 110, a buffer layer 120, an n-type contact layer 130, an n-side electrostatic breakdown-preventing layer 140, an n-side composition gradient layer 150, a light emitting layer 160, an electron blocking layer 170, a p-type contact layer 180, a transparent electrode TE1, a p-electrode P1, and an n-electrode N1.

On a main surface of the substrate 110, the buffer layer 120, the n-type contact layer 130, the n-side electrostatic breakdown-preventing layer 140, the n-side composition gradient layer 150, the light emitting layer 160, the electron blocking layer 170, and the p-type contact layer 180 are formed in this order. The n-electrode N1 is formed on the n-type contact layer 130. The p-electrode P1 is formed on the transparent electrode TEL Here, the n-type contact layer 130, the n-side electrostatic breakdown-preventing layer 140, and the n-side composition gradient layer 150 are n-type semiconductor layers. The electron blocking layer 170 and the p-type contact layer 180 are p-type semiconductor layers. However, these layers may partially include a non-doped layer. As described above, the light emitting device 100 includes the n-type semiconductor layers, the light emitting layer on the n-type semiconductor layers, the p-type semiconductor layers on the light emitting layer, the transparent electrode TE1 on the p-type semiconductor layers, the p-electrode P1 on the transparent electrode TE1, and the n-electrode N1 on the n-type semiconductor layer.

The substrate 110 is a support substrate that supports the semiconductor layers. The main surface of the substrate 110 is, for example, a c-plane. The substrate 110 is, for example, a heterogeneous substrate such as a sapphire substrate, an AlN substrate, a Si substrate, or a SiC substrate. The substrate 110 may be a GaN substrate.

The buffer layer 120 is formed on the main surface of the substrate 110. When the heterogeneous substrate such as the sapphire substrate is used, the buffer layer 120 is, for example, a low-temperature AlN buffer layer. The buffer layer 120 may be a layer other than the low-temperature AlN buffer layer. When a homosubstrate such as the GaN substrate is used, the buffer layer 120 may not be provided.

The n-type contact layer 130 is a layer in contact with the n-electrode N1. The n-type contact layer 130 is formed on the buffer layer 120. The n-type contact layer 130 is, for example, an n-type GaN layer doped with Si. The n-type contact layer 130 may be an n-type AlGaN layer.

The n-side electrostatic breakdown-preventing layer 140 is an electrostatic breakdown-preventing layer for preventing electrostatic breakdown of the semiconductor layer. The n-side electrostatic breakdown-preventing layer 140 is formed on the n-type contact layer 130. The n-side electrostatic breakdown-preventing layer 140 is formed by stacking, for example, an i-AlGaN layer made of non-doped i-AlGaN (0≤Al<1) and an n-type AlGaN layer made of n-type AlGaN (0≤Al<1) doped with Si.

The n-side composition gradient layer 150 is a foundation layer that mitigates strain applied to the light emitting layer 160. The n-side composition gradient layer 150 is located on the n-side electrostatic breakdown-preventing layer 140. As will be described later, in the n-side composition gradient layer 150, composition changes in a thickness direction. The n-side composition gradient layer 150 is located between the n-side electrostatic breakdown-preventing layer 140 and the light emitting layer 160. In addition, the n-side composition gradient layer 150 is located between the substrate 110 and the light emitting layer 160. The n-side composition gradient layer 150 is, for example, an InGaN layer. The n-side composition gradient layer 150 is a layer not doped with impurities.

The light emitting layer 160 is an active layer that emits light by recombination of electrons and holes. The light emitting layer 160 is formed on the n-side composition gradient layer 150. The light emitting layer 160 includes well layers 161 and barrier layers 162. The well layer 161 is a group III nitride semiconductor layer containing In. The barrier layer 162 is a group III nitride semiconductor layer. The well layers 161 and the barrier layers 162 are alternately and repeatedly formed. A thickness of the well layer 161 is, for example, 2 nm or more and 10 nm or less. In composition of the well layer 161 is, for example, 15% or more, preferably 25% or more, and more preferably, 35% or more. The number of well layers 161 is, for example, one or more and three or less, and of course, may be four or more. The well layer 161 is, for example, an InGaN layer. The barrier layer 162 is, for example, a GaN layer. As long as a band gap of the barrier layer 162 is larger than a band gap of the well layer 161, the well layer 161 and the barrier layer 162 may have other compositions.

The electron blocking layer 170 is a layer that blocks electrons. The electron blocking layer 170 is formed on the light emitting layer 160. The electron blocking layer 170 is formed by repeatedly forming, for example, a stacked body in which a p-type GaN layer, a p-type AlGaN layer, and a p-type InGaN layer are stacked. The p-type AlGaN layer of the electron blocking layer 170 has the function of blocking electrons. Therefore, the p-type GaN layer and the p-type InGaN layer may not be provided. That is, the electron blocking layer 170 may be the single p-type AlGaN layer.

The p-type contact layer 180 is a semiconductor layer electrically connected to the p-electrode P1. The p-type contact layer 180 is in contact with the transparent electrode TEE The p-type contact layer 180 is formed on the electron blocking layer 170. The p-type contact layer 180 is, for example, a p-type GaN layer doped with Mg. The p-type contact layer 180 may be a p-type AlGaN layer.

The transparent electrode TE1 is formed on the p-type contact layer 180. A material of the transparent electrode TE1 is, for example, ITO. In addition to ITO, transparent conductive oxides such as IZO, ICO, ZnO, TiO₂, NbTiO₂, and TaTiO₂ can be used.

The p-electrode P1 is formed on the transparent electrode TEE The p-electrode P1 is electrically connected to the p-type contact layer 180 via the transparent electrode TEE The p-electrode P1 is, for example, a metal electrode made of a metal such as Ni, Au, Ag, Co, or In.

The n-electrode N1 is formed on the n-type contact layer 130. The n-electrode N1 is in contact with the n-type contact layer 130. The n-electrode N1 is, for example, a metal electrode made of a metal such as Ni, Au, Ag, Co, In, or Ti.

### 2. Composition Gradient Layer

2-1. Band Structure and In Composition

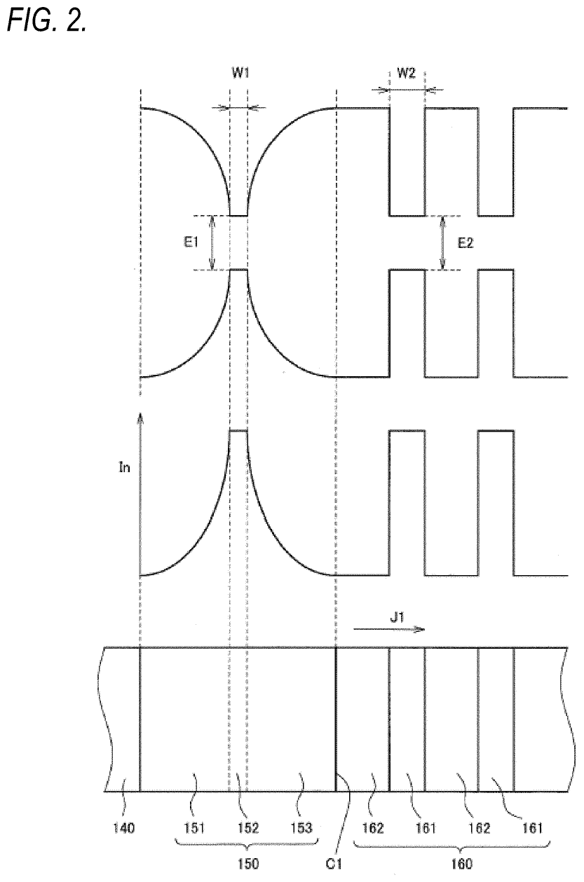

FIG. 2 is a diagram showing a relationship between a band structure and a stacked structure of the n-side composition gradient layer 150 and the light emitting layer 160 of the light emitting device 100 according to the first embodiment. The stacked structure, the In composition, and the band structure of the semiconductor are shown in order from a lower side of FIG. 2.

The n-side composition gradient layer 150 includes a composition continuous gradient layer 151, an intermediate layer 152, and a composition continuous gradient layer 153. The composition continuous gradient layer 151 is located between the electrostatic breakdown-preventing layer 140 and the intermediate layer 152. The intermediate layer 152 is located between the composition continuous gradient layer 151 and the composition continuous gradient layer 153. The composition continuous gradient layer 153 is located between the intermediate layer 152 and the barrier layer 162.

The intermediate layer 152 is located between the composition continuous gradient layer 151 and the light emitting layer 160. The composition continuous gradient layer 153 is located between the intermediate layer 152 and the light emitting layer 160.

The intermediate layer 152 is the group III nitride semiconductor layer containing In.

The composition continuous gradient layer 151 and the composition continuous gradient layer 153 are group III nitride semiconductor layers in which the In composition changes in a direction perpendicular to a boundary surface between the well layer 161 and the barrier layer 162. In the composition continuous gradient layer 151 and the composition continuous gradient layer 153, the In composition continuously changes in a streamline manner toward the intermediate layer 152.

Here, “continuously changes in a streamline manner” indicates a change in a curved shape as shown in FIG. 2 and the like, and does not include a change in a linear manner.

In the composition continuous gradient layer 151 and the composition continuous gradient layer 153, the In composition continuously changes in a streamline manner with respect to a stacking direction J1 perpendicular to a semiconductor formation surface of the substrate 110. Therefore, in the composition continuous gradient layer 151 and the composition continuous gradient layer 153, band energy continuously changes in a streamline manner with respect to the stacking direction J1 perpendicular to the semiconductor formation surface of the substrate 110.

In the composition continuous gradient layer 151, as the In composition approaches the light emitting layer 160, the In composition exponentially increases. Therefore, in the composition continuous gradient layer 151, as the band energy approaches the light emitting layer 160, band energy on an electron side (conduction band) exponentially decreases. As described above, the band energy also changes exponentially with the exponential change of the In composition.

In the intermediate layer 152, the In composition is constant. Therefore, the band energy is also constant in the intermediate layer 152. As a result, a band gap is also constant.

In the composition continuous gradient layer 153, as the In composition approaches the light emitting layer 160, the In composition exponentially decreases. Therefore, in the composition continuous gradient layer 153, as the band energy approaches the light emitting layer 160, the band energy on the electron side (conduction band) exponentially increases. As described above, the band energy also changes exponentially with the exponential change of the In composition.

In the composition continuous gradient layer 151, as the In composition approaches the light emitting layer 160, the In composition exponentially increases. Therefore, as a lattice constant of the composition continuous gradient layer 151 approaches the light emitting layer 160, the lattice constant of the composition continuous gradient layer 151 increases so as to approach a lattice constant of the well layer. As described above, the lattice constant also changes exponentially with the exponential change of the In composition.

In the intermediate layer 152, the In composition is constant. Therefore, the lattice constant is also constant in the intermediate layer 152.

In the composition continuous gradient layer 153, as the In composition approaches the light emitting layer 160, the In composition exponentially decreases. Therefore, as a lattice constant of the composition continuous gradient layer 153 approaches the light emitting layer 160, the lattice constant of the composition continuous gradient layer 153 decreases so as to approach a lattice constant of the barrier layer. As described above, the lattice constant also changes exponentially with the exponential change of the In composition.

2-2. Relationship Between Composition Gradient Layer and Light Emitting Layer

A band gap of the composition continuous gradient layer 151 increases as a distance from the barrier layer 162 increases. The band gap of the composition continuous gradient layer 151 decreases as the band gap approaches the intermediate layer 152.

The composition continuous gradient layer 153 is in contact with the barrier layer 162. A band gap of the composition continuous gradient layer 153 increases as the band gap approaches the barrier layer 162. The band energy of the composition continuous gradient layer 153 asymptotically approaches band energy of the barrier layer 162. That is, the band energy of the composition continuous gradient layer 153 is equal to the band energy of the barrier layer 162 at a contact surface Cl between the composition continuous gradient layer 153 and the barrier layer 162. Therefore, at the contact surface Cl between the composition continuous gradient layer 153 and the barrier layer 162, the In composition of the composition continuous gradient layer 153 and the In composition of the barrier layer 162 are preferably the same.

A thickness W1 of the intermediate layer 152 of the n-side composition gradient layer 150 in the stacking direction J1 is thinner than a thickness W2 of the well layer 161 of the light emitting layer 160 in the stacking direction J1. Therefore, absorption of light in the intermediate layer 152 of the n-side composition gradient layer 150 is prevented. Therefore, the intermediate layer 152 is preferably thin. The intermediate layer 152 may be a single atomic layer.

A band gap E1 of the intermediate layer 152 of the n-side composition gradient layer 150 is equal to or larger than a band gap E2 of the well layer 161 of the light emitting layer 160. That is, the In composition of the intermediate layer 152 of the n-side composition gradient layer 150 is equal to or less than the In composition of the well layer 161 of the light emitting layer 160. Therefore, absorption of light in the intermediate layer 152 of the n-side composition gradient layer 150 is prevented.

The lattice constant of the composition continuous gradient layer 151 decreases as the distance from the barrier layer 162 increases. The lattice constant of the composition continuous gradient layer 151 increases as the lattice constant approaches the intermediate layer 152.

The composition continuous gradient layer 153 is in contact with the barrier layer 162. The lattice constant of the composition continuous gradient layer 153 decreases as the lattice constant approaches the barrier layer 162. The lattice constant of the composition continuous gradient layer 153 asymptotically approaches a lattice constant of the barrier layer 162. That is, the lattice constant of the composition continuous gradient layer 153 is equal to the lattice constant of the barrier layer 162 at the contact surface Cl between the composition continuous gradient layer 153 and the barrier layer 162. Therefore, at the contact surface Cl between the composition continuous gradient layer 153 and the barrier layer 162, the lattice constant of the composition continuous gradient layer 153 and the lattice constant of the barrier layer 162 are preferably the same. The lattice constant of the composition continuous gradient layer 153 increases as the lattice constant approaches the intermediate layer 152.

A lattice constant of the well layer 161 of the light emitting layer 160 is equal to or larger than the lattice constant of the intermediate layer 152 of the n-side composition gradient layer 150. The lattice constant of the intermediate layer 152 of the n-side composition gradient layer 150 is larger than an average value of the lattice constants of the composition continuous gradient layers 151, 153. The average value of the lattice constants of the composition continuous gradient layers 151, 153 is larger than the lattice constant of the barrier layer 162 of the light emitting layer 160.

### 3. Method for Forming Composition Gradient Layer and Light Emitting Layer

3-1. First Method

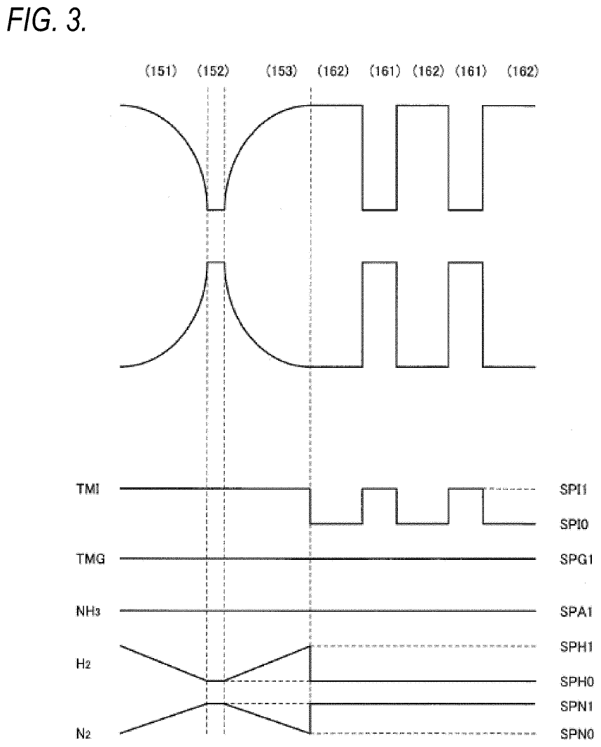

FIG. 3 is a diagram (part 1) showing a method for forming the n-side composition gradient layer 150 and the light emitting layer 160 of the light emitting device 100 according to the first embodiment. FIG. 3 shows a correspondence relationship between the band structures of the n-side composition gradient layer 150 and the light emitting layer 160 and supply amounts of gases. FIG. 3 shows a case where the well layer 161 is made of InGaN and the barrier layer 162 is made of GaN. In FIG. 3, time elapses from a left side to a right side. In the first embodiment, the n-side composition gradient layer 150 and the light emitting layer 160 are epitaxially grown by a metal organic chemical vapor deposition method (MOCVD method).

A carrier gas used here contains hydrogen (H₂). The carrier gas may contain nitrogen (N₂). Ammonia gas (NH₃) is used as a nitrogen source. Trimethylgallium (Ga(CH₃)₃: “TMG”) is used as a Ga source. Trimethylindium (In(CH₃)₃: “TMI”) is used as an In source.

As shown in FIG. 3, a flow rate of TMG is constant at a supply amount SPG1. A flow rate of NH₃ is constant at a supply amount SPA1. A flow rate of N₂ is changed between a supply amount SPN1 and a supply amount SPN0, such that a sum of a supply amount of H₂ and a supply amount of N₂ is constant.

A flow rate of TMI is set to a value of a supply amount SPI1 or a value of a supply amount SPI0. The value of the supply amount SPI1 is larger than the value of the supply amount SPI0. The supply amount SPI0 of TMI is, for example, 0 sccm. A flow rate of H₂ is changed between a supply amount SPH0 and a supply amount SPH1. A value of the supply amount SPH1 is larger than a value of the supply amount SPH0. The supply amount SPH0 of H₂ is, for example, 0 sccm.

When the composition continuous gradient layer 151 is grown, the composition continuous gradient layer 151 is grown while changing the flow rate of hydrogen gas. For example, the flow rate of H₂ is linearly decreased from the supply amount SPH1 to the supply amount SPH0 while TMI flows at the constant supply amount SPI1. Even when the flow rate of TMI is a constant value, the In composition exponentially increases by linearly decreasing the flow rate of H₂.

A reason why the In composition exponentially changes is considered to be that hydrogen gas etches In to a certain extent. When a ratio of hydrogen gas exceeds a value of the certain extent, most of In is etched. In this case, GaN or GaN with In added at a dope level grows.

When the intermediate layer 152 is grown, the flow rate of H₂ is set to the constant supply amount SPH0 while TMI flows at the constant supply amount SPI1. Thereby, the intermediate layer 152 having a constant In composition is formed in the stacking direction J1.

When the composition continuous gradient layer 153 is grown, the composition continuous gradient layer 153 is grown while changing the flow rate of hydrogen gas. For example, the flow rate of H₂ is linearly increased from the supply amount SPH0 to the supply amount SPH1 while TMI flows at the constant supply amount SPI1. Even when the flow rate of TMI is the constant value, the In composition exponentially decreases by linearly increasing the flow rate of H₂.

As described above, in a step of growing the n-side composition gradient layer 150 as the foundation layer, the composition continuous gradient layer 151 is grown while linearly decreasing the flow rate of hydrogen gas. After the composition continuous gradient layer 151 is grown, the intermediate layer 152 is grown while keeping the flow rate of hydrogen gas constant. After the intermediate layer 152 is grown, the composition continuous gradient layer 153 is grown while linearly increasing the flow rate of hydrogen gas.

When the light emitting layer 160 is grown, the flow rates of TMG, NH₃, H₂, and Na are constant. The flow rate of TMI is switched to either the supply amount SPI1 or the supply amount SPI0. As long as the supply amount SPI0 is 0 sccm, the GaN layer is formed.

3-2. Second Method

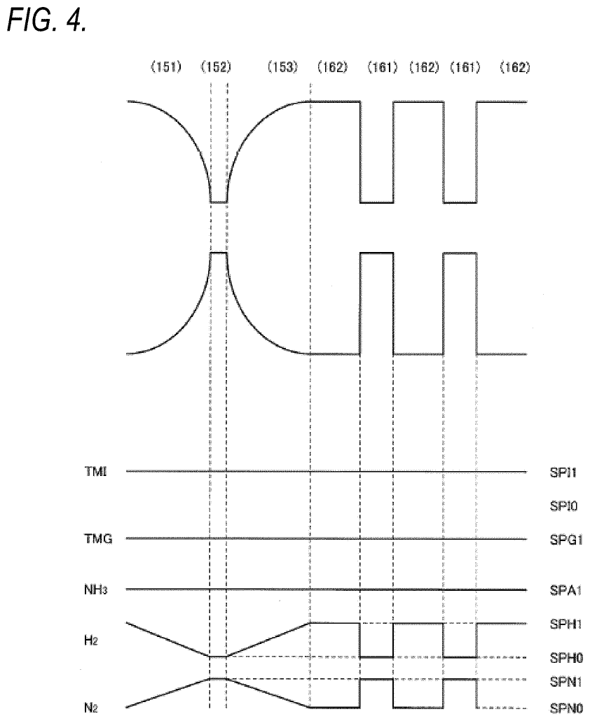

FIG. 4 is a diagram (part 2) showing a method for forming the n-side composition gradient layer 150 and the light emitting layer 160 of the light emitting device 100 according to the first embodiment. As shown in FIG. 4, the flow rate of TMG is constant at the supply amount SPG1. The flow rate of NH₃ is constant at the supply amount SPA1. The flow rate of Na is changed between the supply amount SPN1 and the supply amount SPN0, such that the sum of the supply amount of H₂ and the supply amount of Na is constant.

The flow rate of TMI is set to a constant value at the supply amount SPI1. The flow rate of H₂ is changed between the supply amount SPH0 and the supply amount SPH1. The value of the supply amount SPH1 is larger than the value of the supply amount SPH0. The supply amount SPH0 of H₂ is, for example, about 0.5% of a total supply amount of the supply amount of H₂ and the supply amount of Na.

When the composition continuous gradient layer 151 is grown, the composition continuous gradient layer 151 is grown while changing the flow rate of hydrogen gas. For example, the flow rate of H₂ is linearly decreased from the supply amount SPH1 to the supply amount SPH0 while TMI flows at the constant supply amount SPI1. Even when the flow rate of TMI is a constant value, the In composition exponentially increases by linearly decreasing the flow rate of H₂.

A reason why the In composition exponentially changes is considered to be that hydrogen gas etches In to a certain extent. When a ratio of hydrogen gas exceeds a value of the certain extent, most of In is etched. In this case, GaN or GaN with In added at a dope level grows.

When the intermediate layer 152 is grown, the flow rate of H₂ is set to the constant supply amount SPH0 while TMI flows at the constant supply amount SPI1. Thereby, the intermediate layer 152 having a constant In composition is formed in the stacking direction J1.

When the composition continuous gradient layer 153 is grown, the composition continuous gradient layer 153 is grown while changing the flow rate of hydrogen gas. For example, the flow rate of H₂ is linearly increased from the supply amount SPH0 to the supply amount SPH1 while TMI flows at the constant supply amount SPI1. Even when the flow rate of TMI is the constant value, the In composition exponentially decreases by linearly increasing the flow rate of H₂.

As described above, in a step of growing the n-side composition gradient layer 150 as the foundation layer, the composition continuous gradient layer 151 is grown while linearly decreasing the flow rate of hydrogen gas. After the composition continuous gradient layer 151 is grown, the intermediate layer 152 is grown while keeping the flow rate of hydrogen gas constant. After the intermediate layer 152 is grown, the composition continuous gradient layer 153 is grown while linearly increasing the flow rate of hydrogen gas.

When the light emitting layer 160 is grown, the flow rates of TMG, TMI, and NH₃ are constant. The flow rate of H₂ is switched to either the supply amount SPH1 or the supply amount SPH0. As long as the supply amount SPH0 is about 0.5% of the total supply amount of the supply amount of H₂ and the supply amount of N₂, a high-quality InGaN well layer is formed. As long as the supply amount SPH1 is about 10% of the total supply amount of the supply amount of H₂ and the supply amount of N₂, an InGaN barrier layer having a low In composition or In added at a dope level is formed.

### 4. Method for Producing Semiconductor Light Emitting Device

A method for producing the light emitting device 100 according to the first embodiment will be described. In the first embodiment, crystals of the semiconductor layers are epitaxially grown by the metal organic chemical vapor deposition method (MOCVD method). This producing method includes a step of growing the foundation layer including the intermediate layer 152 and the composition continuous gradient layers 151, 153 on the substrate 110, and a step of growing the light emitting layer 160 including the well layers 161 and the barrier layers 162 above the foundation layer.

An internal pressure of a MOCVD furnace is, for example, 1 kPa or more and 1 MPa or less. It is preferable to perform the growth under a reduced pressure as necessary. This is because as an internal pressure in a semiconductor producing apparatus when the growth is performed decreases, lateral growth of the semiconductor layer is further promoted. This is because migration of a raw material on a surface of the substrate is promoted. Under high temperature conditions, the migration of the raw material on the surface of the substrate is further promoted.

The substrate 110 is prepared. The buffer layer 120, the n-type contact layer 130, the n-side electrostatic breakdown-preventing layer 140, the n-side composition gradient layer 150, the light emitting layer 160, the electron blocking layer 170, and the p-type contact layer 180 are formed in this order on the main surface of the substrate 110.

Next, the transparent electrode TE1 is formed on the p-type contact layer 180 by sputtering or the like. Next, a concave portion reaching the n-type contact layer 130 from the p-type contact layer 180 is formed. The n-electrode N1 is formed on the exposed n-type contact layer 130, and the p-electrode P1 is formed on the transparent electrode TEL In addition, heat treatment steps or the like other than the above may be performed.

### 5. Effects of First Embodiment

The light emitting device 100 according to the first embodiment includes the n-side composition gradient layer 150 immediately below the light emitting layer 160. In the composition continuous gradient layers 151, 153, the In composition changes exponentially. Therefore, a stress applied to the light emitting layer 160 from a substrate 110 side is prevented. Thereby, the strain is mitigated. As a result, crystal quality is improved, and a piezoelectric field to be formed is weakened. Therefore, the light emitting device 100 has high light emission efficiency.

When the layers are stacked on a plane perpendicular to a polarity direction, for example, a c-axis direction, that is, a [0001] axis direction, or a plane off from these planes, an effect of improving internal quantum efficiency due to the weakness of the piezoelectric field is obtained in addition to the effect of improving of the crystal quality due to the mitigation of the strain. A ratio of these effects varies depending on a crystal plane on which the crystals are stacked.

When the layers are stacked on the plane perpendicular to the polarity direction, in addition to the effect of improving of the crystal quality, there is a difference in effect depending on a direction of a polarity. When the layers are stacked along a −c-axis direction, that is, a [000-1] axis direction, a direction of the piezoelectric field and a direction of an internal field are opposite to each other. Therefore, the piezoelectric field is somewhat weakened, and the effect of weakening the piezoelectric field due to the mitigation of the strain is obtained.

On the other hand, when the layers are stacked along the +c-axis direction, that is, the [0001] axis direction, the effect of weakening the piezoelectric field due to the mitigation of the strain is remarkable.

In addition, when the layers are stacked on a nonpolar plane perpendicular to an m-axis or an a-axis, a semipolar plane perpendicular to an r-axis, or a plane off from these planes, the effect of improving the crystal quality is particularly high.

As described above, regardless of the crystal plane to which the technique of the first embodiment is applied, the crystal quality is improved, and an effect of improving device characteristics is obtained. In particular, it is preferable that when the layers are stacked in the c-axis direction, both the effect of improving the crystal quality and the effect of weakening the piezoelectric field can be effectively obtained.

In addition, it is not necessary to provide a superlattice layer between the substrate 110 and the light emitting layer 160. The superlattice layer is a layer formed by repeatedly forming two layers having different compositions. Since it is not necessary to provide the superlattice layer, the stacked structure is simple. In addition, a produce time for producing the light emitting device 100 can be shortened.

The thickness of the intermediate layer 152 is smaller than the thickness of the well layer 161. Therefore, energy of a subband formed in the intermediate layer 152 is higher than energy of a subband formed in the well layer 161. Therefore, the absorption of light in the intermediate layer 152 hardly occurs.

### 6. Modifications

6-1. Temporal Change of TMI

In the first embodiment, the flow rate of TMI at the time of forming the composition continuous gradient layers 151, 153 is set to the constant supply amount SPI1. However, when the composition continuous gradient layers 151, 153 are grown, the flow rate of TMI may be changed. Even when TMI is changed, the In composition can be changed exponentially. For example, the flow rate of TMI may be changed while changing the flow rate of H₂.

6-2. Flow Rate of TMI

The flow rate of TMI when the intermediate layer 152 of the composition gradient layer 150 is grown may be different from the flow rate of TMI when the well layer 161 of the light emitting layer 160 is grown. In this case, the flow rate of TMI when the well layer 161 of the light emitting layer 160 is grown is higher than the flow rate of TMI when the intermediate layer 152 of the composition gradient layer 150 is grown.

6-3. Plurality of Layers

A plurality of n-side composition gradient layers 150 may be repeatedly formed. The number of times for the repeat formation is, for example, five or less, and preferably, three or less.

6-4. Presence/Absence of Intermediate Layer

The composition gradient layer 150 may not include the intermediate layer 152. In this case, the composition continuous gradient layers 151, 153 come into contact with each other.

6-5. Well Layer and Barrier Layer

The well layer 161 is not limited to the InGaN layer, and the barrier layer 162 is not limited to the GaN layer. The well layer 161 may be a layer as long as being made of a group III nitride semiconductor. The barrier layer 162 may be a layer as long as being made of a group III nitride semiconductor. However, the band gap of the barrier layer 162 is larger than the band gap of the well layer 161.

6-6. AlInGaN Layer

The composition continuous gradient layers 151, 153 and the intermediate layer 152 may be a group III nitride semiconductor layer other than the InGaN layer.

6-7. Thickness

The thicknesses of the composition continuous gradient layers 151, 153 and the intermediate layer 152 are not particularly limited. The thickness of the intermediate layer 152 may be one atomic layer or more and 5 nm or less. The thickness of the composition continuous gradient layers 151, 153 is preferably 3 nm or more and 100 nm or less, more preferably, 5 nm or more and 50 nm or less, and much more preferably, 5 nm or more and 30 nm or less.

6-8. Layer Forming Rate

Layer forming rates of the composition continuous gradient layers 151, 153 and the intermediate layer 152 are not particularly limited. From a viewpoint of quality of the semiconductor layer, the layer forming rate may be 0.5 nm/min or more and 50 nm/min or less.

6-9. Only One Composition Gradient Layer

Only one of the composition continuous gradient layer 151 and the composition continuous gradient layer 153 may be formed. In this case, the intermediate layer 152 is interposed between a semiconductor layer having a band gap larger than that of the intermediate layer 152 and the composition continuous gradient layer.

6-10. Supply of Hydrogen Gas

In the first embodiment, the supply amount of hydrogen gas is linearly changed. However, an amount of the change in the supply amount of hydrogen gas may be changed in the middle. In this case, the supply amount of hydrogen gas undergoes two or more linear changes with different slopes.

6-11. Face-Down Semiconductor Light Emitting Device

The technique of the first embodiment may be applied not only to the face-up LED but also to a face-down LED. In this case, a metal electrode having a high reflectance may be used instead of the transparent electrode.

6-12. Conductive

The n-side composition gradient layer 150 is a layer not doped with impurities. However, the n-side composition gradient layer 150 may be doped with an n-type impurity or a p-type impurity.

6-13. Electrostatic Breakdown-Preventing Layer

In some cases, the electrostatic breakdown-preventing layer 140 may not be formed.

6-14. Combination

The above modifications may be freely combined.

### Second Embodiment

A second embodiment will be described.

1. Laser Device

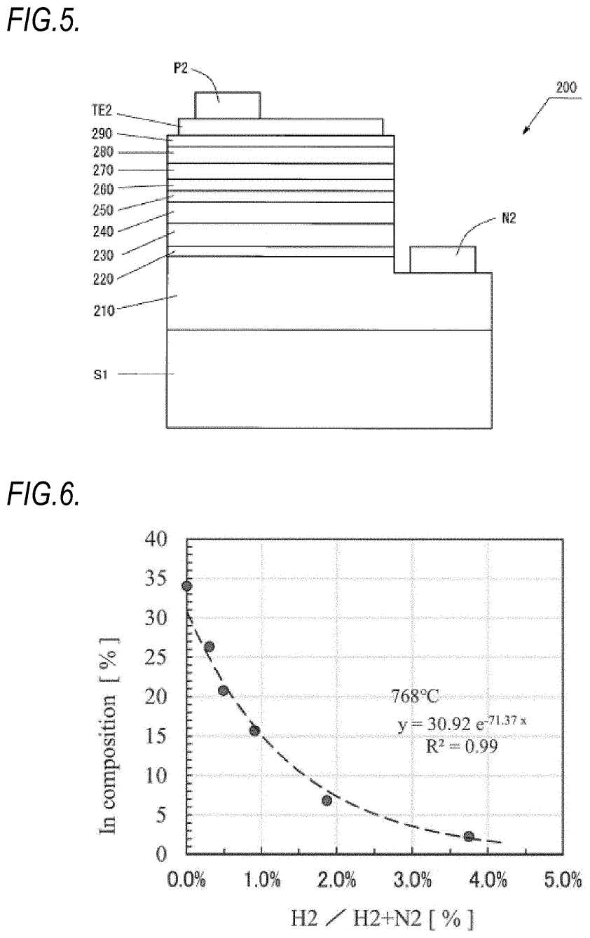

FIG. 5 is a schematic configuration diagram of a laser device 200 according to the second embodiment. The laser device 200 includes a substrate 51, an n-type contact layer 210, an n-side cladding layer 220, an n-side guide layer 230, an n-side composition gradient layer 240, an active layer 250, a p-side guide layer 260, a p-side electron barrier layer 270, a p-side cladding layer 280, a p-type contact layer 290, a transparent electrode TE2, an n-electrode N₂, and a p-electrode P2.

The n-side composition gradient layer 240 includes a first composition continuous gradient layer, an intermediate layer, and a second composition continuous gradient layer.

### 2. Effects of Second Embodiment

As in the first embodiment, in the laser device 200, strain applied to the active layer 250 is mitigated.

### 3. Modifications

The first embodiment and the modifications thereof may be freely combined.

### Third Embodiment

A third embodiment will be described.

1. Semiconductor Light Emitting Device (Three-Dimensional Structure)

The intermediate layer and the composition continuous gradient layers of the first embodiment and the second embodiment can be applied to a three-dimensional structure. For example, the three-dimensional structure is a columnar three-dimensional crystal such as a nanowire. In a case of a stack type in which an active layer is inserted in the middle of the nanowire, the intermediate layer and the composition continuous gradient layer can be provided at a position adjacent to the active layer. Similarly, in a case of a core-shell type in which a periphery of the nanowire is coaxially covered with the active layer, the intermediate layer and the composition continuous gradient layer can be provided at a position adjacent to the active layer.

The intermediate layer and the composition continuous gradient layer are not limited to being stacked on flat surfaces, and are also applicable to a semiconductor light emitting device in which a three-dimensional structure has a triangular shape, a trapezoidal shape, a dot shape, or a stripe shape. By including the intermediate layer and the composition continuous gradient layer, the semiconductor light emitting device exhibits the same effects. Of course, the same effects can be exhibited even when the invention is applied to an active layer formed in a three-dimensional structure including various crystal planes.

(Combination of Embodiments)

The first embodiment to the third embodiment may be combined together including the modifications.

(Evaluation Test)

1. Preparation of Sample

In order to prepare a sample, the MOCVD method was used. A template substrate in which a GaN layer was grown on a GaN substrate was prepared. Then, TMI, TMG, NH₃, H₂, and N₂ were supplied onto the GaN layer to form an InGaN layer. At this time, the flow rate of H₂ and the flow rate of TMI were changed. Then, the In composition and the like of the grown semiconductor were measured.

2. Hydrogen Gas and In Composition

FIG. 6 is a graph (part 1) showing a relationship between a flow rate of hydrogen gas in a carrier gas and an In composition of a semiconductor. A horizontal axis of FIG. 6 represents the flow rate (vol %) of hydrogen gas in the carrier gas. A vertical axis of FIG. 6 represents the In composition of the semiconductor.

As shown in FIG. 6, when the flow rate of hydrogen gas in the carrier gas increases, the In composition of the semiconductor decreases exponentially. On the other hand, when the flow rate of hydrogen gas in the carrier gas decreases, the In composition of the semiconductor increases exponentially.

In general, the In composition (In/Ga solid phase ratio) has a value lower than that of an In/Ga gas phase ratio. The In/Ga gas phase ratio is a partial pressure of TMI supply with respect to a partial pressure of TMG supply. This is because In has a lower surface adsorption force than that of Ga and is easily decomposed and re-evaporated by heat or etching gas. When hydrogen gas, which is a carrier gas having an etching effect, is not contained, the In composition (In/Ga solid phase ratio) is closest to the In/Ga gas phase ratio. As an amount of hydrogen gas in the carrier gas increases, the In composition decreases. It is considered that this is because hydrogen gas etches In.

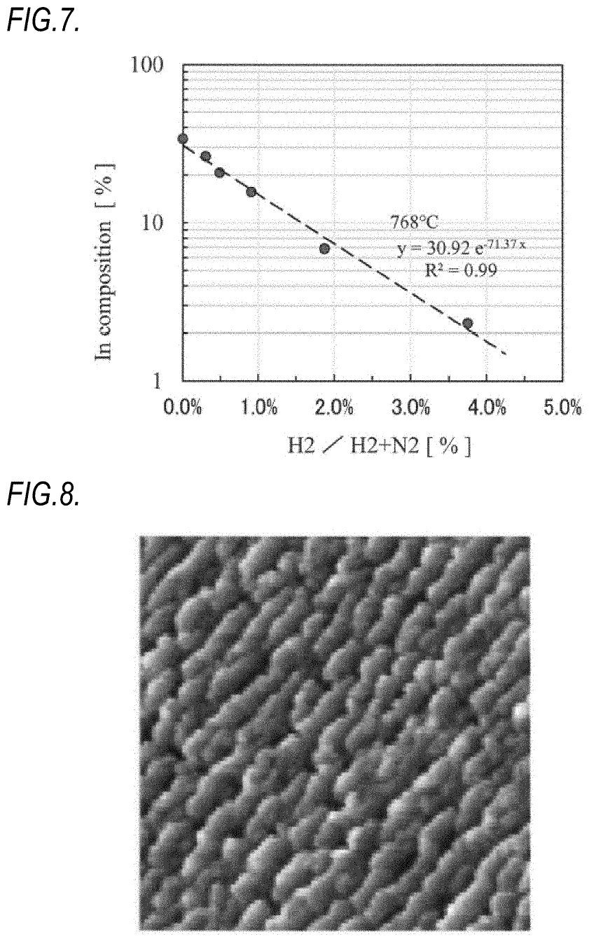

FIG. 7 is a graph (part 2) showing the relationship between the flow rate of hydrogen gas in the carrier gas and the In composition of the semiconductor. FIG. 7 is a graph in which the vertical axis of FIG. 6 is a logarithm. As shown in FIG. 7, the measured value of the In composition lies on a certain straight line. That is, the In composition exponentially changes with respect to the flow rate of hydrogen gas in the carrier gas.

3. AFM Image

FIG. 8 is an AFM image of a surface of the light emitting layer when the n-side composition gradient layer is formed. In FIG. 8, atomic steps are observed.

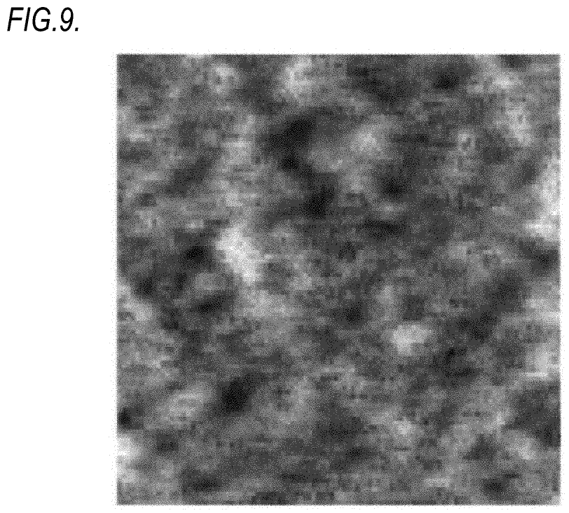

FIG. 9 is an AFM image of the surface of the light emitting layer without the n-side composition gradient layer. In FIG. 9, atomic steps are observed. In addition, pits and surface roughness are generated.

4. Photoluminescence

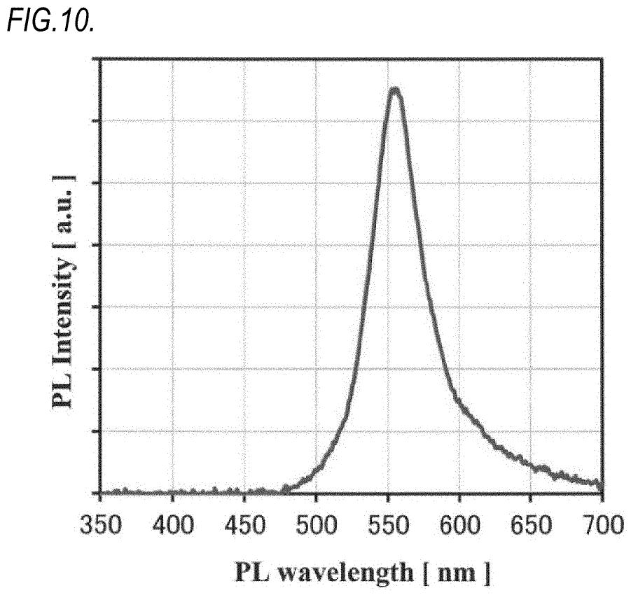

FIG. 10 is a graph showing a photoluminescence intensity of the semiconductor light emitting device when the n-side composition gradient layer is formed. A horizontal axis of FIG. 10 represents a peak wavelength of photoluminescence. A vertical axis of FIG. 10 represents the photoluminescence intensity.

When the n-side composition gradient layer is not provided, no photoluminescence emission was observed.

5. Summary of Evaluation Test

As described above, the composition gradient layer mitigates the strain. Therefore, crystallinity of an upper layer semiconductor such as the light emitting layer is improved.

(Appendix)

A group III nitride semiconductor device according to a first aspect includes a substrate, an active layer, and a foundation layer between the substrate and the active layer. The active layer includes a well layer and a barrier layer. The foundation layer includes a composition continuous gradient layer. The well layer is a group III nitride semiconductor layer containing In. The barrier layer is a group III nitride semiconductor layer. The composition continuous gradient layer is a group III nitride semiconductor layer in which an In composition changes in a direction perpendicular to a boundary surface between the well layer and the barrier layer. In the composition continuous gradient layer, the In composition continuously changes in a streamline manner.

In a group III nitride semiconductor device according to a second aspect, the foundation layer includes an intermediate layer. The intermediate layer is a group III nitride semiconductor layer containing In. A thickness of the intermediate layer is smaller than a thickness of the well layer. An In composition of the intermediate layer is equal to or less than an In composition of the well layer. In the composition continuous gradient layer, the In composition continuously changes in a streamline manner toward the intermediate layer.

In a group III nitride semiconductor device according to a third aspect, the composition continuous gradient layer includes a first composition continuous gradient layer in which as an In composition approaches the active layer, the In composition exponentially increases. The intermediate layer is located between the first composition continuous gradient layer and the active layer.

In a group III nitride semiconductor device according to a fourth aspect, the composition continuous gradient layer includes a second composition continuous gradient layer in which as the In composition approaches the active layer, the In composition exponentially decreases. The second composition continuous gradient layer is located between the intermediate layer and the active layer.

In a group III nitride semiconductor device according to a fifth aspect, the second composition continuous gradient layer is in contact with the barrier layer of the active layer. At a contact position, the In composition of the second composition continuous gradient layer and an In composition of the barrier layer are the same.

In a group III nitride semiconductor device according to a sixth aspect, a lattice constant of the well layer is equal to or larger than a lattice constant of the intermediate layer.

In a group III nitride semiconductor device according to a seventh aspect, the lattice constant of the intermediate layer is larger than an average value of lattice constants of the composition continuous gradient layers. The average value of the lattice constants of the composition continuous gradient layers is larger than a lattice constant of the barrier layer.

A method for producing a group III nitride semiconductor device according to an eighth aspect includes a step of growing a foundation layer including an intermediate layer and a composition continuous gradient layer on a substrate, and a step of growing a light emitting layer including a well layer and a barrier layer above the foundation layer. The well layer is a group III nitride semiconductor layer containing In. The barrier layer is a group III nitride semiconductor layer. The intermediate layer is a group III nitride semiconductor layer containing In. The composition continuous gradient layer is a group III nitride semiconductor layers in which an In composition changes in a stacking direction. In the step of growing the foundation layer, a gas containing hydrogen gas is used as a carrier gas, and the composition continuous gradient layer is grown while changing a flow rate of hydrogen gas.

In a method for producing a group III nitride semiconductor device according to a ninth aspect, in the step of growing the foundation layer, the flow rate of hydrogen gas is linearly changed.

In a method for producing a group III nitride semiconductor device according to a tenth aspect, in the step of growing the foundation layer, the first composition continuous gradient layer is grown while the flow rate of hydrogen gas is linearly decreased, the intermediate layer is grown while the flow rate of hydrogen gas is kept constant after the first composition continuous gradient layer is grown, and the second composition continuous gradient layer is grown while the flow rate of hydrogen gas is linearly increased after the intermediate layer is grown.

What is claimed is:

1. A group III nitride semiconductor device comprising:
a substrate;
an active layer; and
a foundation layer between the substrate and the active layer,
wherein the active layer includes a well layer and a barrier layer,
the foundation layer includes a composition continuous gradient layer,
the well layer is a group III nitride semiconductor layer containing In,
the barrier layer is a group III nitride semiconductor layer,
the composition continuous gradient layer is a group III nitride semiconductor layer in which an In composition changes in a direction perpendicular to a boundary surface between the well layer and the barrier layer, and
the In composition continuously changes in a streamline manner.

2. The group III nitride semiconductor device according to claim 1,
wherein the foundation layer includes an intermediate layer,
the intermediate layer is a group III nitride semiconductor layer containing In,
a thickness of the intermediate layer is smaller than a thickness of the well layer,
an In composition of the intermediate layer is equal to or less than an In composition of the well layer, and
in the composition continuous gradient layer, the In composition continuously changes in a streamline manner toward the intermediate layer.

3. The group III nitride semiconductor device according to claim 2,
wherein the composition continuous gradient layer includes a first composition continuous gradient layer in which as an In composition approaches the active layer, the In composition exponentially increases, and
the intermediate layer is located between the first composition continuous gradient layer and the active layer.

4. The group III nitride semiconductor device according to claim 2,
wherein the composition continuous gradient layer includes a second composition continuous gradient layer in which as an In composition approaches the active layer, the In composition exponentially decreases, and
the second composition continuous gradient layer is located between the intermediate layer and the active layer.

5. The group III nitride semiconductor device according to claim 4,
wherein the second composition continuous gradient layer is in contact with the barrier layer of the active layer, and
at a contact position, the In composition of the second composition continuous gradient layer and an In composition of the barrier layer are the same.

6. The group III nitride semiconductor device according to claim 2,
wherein a lattice constant of the well layer is equal to or larger than a lattice constant of the intermediate layer.

7. The group III nitride semiconductor device according to claim 6,
wherein the lattice constant of the intermediate layer is larger than an average value of lattice constants of the composition continuous gradient layers, and
the average value of the lattice constants of the composition continuous gradient layers is larger than a lattice constant of the barrier layer.

8. A method for producing a group III nitride semiconductor device comprising:
a step of growing a foundation layer including an intermediate layer and a composition continuous gradient layer on a substrate; and
a step of growing a light emitting layer including a well layer and a barrier layer above the foundation layer,
wherein the well layer is a group III nitride semiconductor layer containing In,
the barrier layer is a group III nitride semiconductor layer,
the intermediate layer is a group III nitride semiconductor layer containing In,
the composition continuous gradient layer is a group III nitride semiconductor layers in which an In composition changes in a stacking direction,
in the step of growing the foundation layer, a gas containing hydrogen gas is used as a carrier gas, and
the composition continuous gradient layer is grown while changing a flow rate of hydrogen gas.

9. The method for producing a group III nitride semiconductor device according to claim 8,
wherein in the step of growing the foundation layer, the flow rate of hydrogen gas is linearly changed.

10. The method for producing a group III nitride semiconductor device according to claim 9,
wherein in the step of growing the foundation layer, the first composition continuous gradient layer is grown while the flow rate of hydrogen gas is linearly decreased,
the intermediate layer is grown while the flow rate of hydrogen gas is kept constant after the first composition continuous gradient layer is grown, and
the second composition continuous gradient layer is grown while the flow rate of hydrogen gas is linearly increased after the intermediate layer is grown.
